(19) United States
(12) Patent Application Publication
(10) Pub. No.: US 2026/0273807 A1
(43) Pub. Date: Sep. 17, 2026

(54) METHOD FOR MANUFACTURING A GRAPHENE-BASED THERMAL INTERFACE PAD

(71) Applicant: SHT Smart High-Tech AB, GÖTEBORG (SE)

(72) Inventors: Lars Almhem, GÖTEBORG (SE); Johan Liu, VÄSTRA FRÖLUNDA (SE)

(21) Appl. No.: 19/167,119

(22) PCT Filed: Mar. 15, 2024
(86) PCT No.: PCT/SE2024/050239

§ 371 Date: Sep. 19, 2025

(30) Foreign Application Priority Data
Mar. 21, 2023 (SE) 2350313-9

(51) Int. Cl. B29C 43/20; B29C 43/02; B29K 105/00; B32B 1/00; B32B 9/04; H05K 7/20

(52) U.S. Cl. CPC B29C 43/203; B29C 43/021; B32B 1/00; B32B 9/04; H05K 7/2039; B29K 2105/256; B29K 2995/0013; B29K 2995/0088; B32B 2307/302

(57) ABSTRACT

Method for manufacturing a thermal interface film, the method comprising: providing a stack of graphene-based films; pressing the stack of graphene-based films between a first mould and a second mould to form a compressed film, wherein at least one of the first and second mould has a profiled surface; infiltrating a polymer in the compressed film to form an infiltrated film; curing the infiltrated film; and cutting the cured infiltrated film in a direction perpendicular to the plane of the graphene-based films to form a graphene-enhanced thermal interface pad.

### FIELD OF THE INVENTION

The present invention relates to the field of microelectronics packaging, and especially to thermal interface materials in which heat dissipation is a crucial issue.

### BACKGROUND OF THE INVENTION

With the continuous development of modern electronics devices and systems, their increasing power densities have also caused higher operating temperatures. Therefore, effective thermal management is becoming extremely crucial for removing the large amount of heat required for ensuring high performance and long lifetime reliability. Thermal conductivity of traditional thermal interface materials (TIMs), a very important element for heat dissipation, is often less than max 10 W/mK, usually around 4 or 5 W/mK in vertical directions. Great efforts have hence been made to develop high performance TIMs based on carbon materials (e.g., graphite nano-platelets, carbon nanotubes and carbon fibers) in order to solve this problem.

However, there is still room for further improvement of graphene-enhanced thermal interface materials.

### SUMMARY

In view of above-mentioned and other drawbacks of the prior art, it is an object of the present invention to provide an improved high thermal conductivity interface material and a method for manufacturing the material.

According to a first aspect of the invention, there is provided a method for manufacturing a thermal interface pad, the method comprising: providing (200) a stack of graphene-based films; arranging the stack of graphene-based films in a first profiled mould; pressing the stack of graphene-based films between a first mould and a second mould to form a compressed film, wherein at least one of the first and second mould has a non-flat profiled surface; infiltrating a polymer in the compressed film to form an infiltrated film; curing the infiltrated film; and cutting the cured infiltrated film in a direction perpendicular to the plane of the graphene-based films to form a graphene-enhanced thermal interface pad in which strips of graphene film follow the non-flat profile of the least one of the first and second mould in the plane of the pad.

Graphene-based films have been shown to have very high in-plane thermal conductivity, sometimes in excess of 1000-3000 W/mK, and the present invention aims to implement graphene-based films infiltrated with a polymer material to form a graphene enhanced thermal interface pad having a high thermal conductivity in the vertical direction. That the material is referred to as a pad should be interpreted to mean that the extension in an xy-plane is substantially larger than the thickness of the material. Accordingly, a vertical direction is seen as the direction perpendicular to the xy-plane of the film, i.e. the z-direction. The described thermal interface pad can be formed as pads or patches of appropriate size to be arranged for example between a heat-generating electrical component and a cooling element.

In particular, the present invention is based on the realization that by forming a thermal interface pad where a stack of graphene-based films is arranged to follow a profile instead of being flat, the mechanical properties of the resulting thermal interface pad can be improved. In particular, the flexibility of the pad is improved so that more bending and/or stretching of the pad is allowed without breaking of the pad and without delamination of the layers of graphene-based film.

Moreover, the softness of the thermal interface pad can be improved by up to 2 to 5 times compared to thermal interface materials based on unlayered and/or planar structures. In other words, the compressibility of the thermal interface pad manufactured by the described method is higher than the compressibility of a thermal interface pad where no profiled mould is used. The increased softness improves the contact area and helps to fill in small airgaps between the thermal interface pad and a surface of a component.

The mechanical and thermal properties of the thermal interface pad can be controlled for example by controlling the ratio between polymer and graphene-based film in the. In practice, there may be a trade-off between the mechanical and thermal properties of the film where a larger proportion of polymer would improve the mechanical properties while reducing overall thermal conductivity.

In the present context, the non-flat profiled surface of at least one of the first and second mould should be interpreted as a macroscopically profiled surface having a shape which is subsequently transferred to the stack of graphene-based films. Typically, the surface is visibly non-flat.

According to one embodiment of the invention, the first mould has a concave profile or an undulating profile. The second mould may be either flat or it may have a profile mirroring the profile of the first mould. For a first mould having a concave profile, the second mould may have a correspondingly convex profile so that the resulting compressed film has a curved or “U-shaped” surface profile following the profile of the first and second mold. The curved molds result in a thermal interface pad having curved strips of the graphene-based film stacked in the plane of the pad, which in turn leads to improved mechanical properties of the thermal interface.

In embodiments where the first also has an undulating or wave-shaped profile, the second mold may have a corresponding wave-shaped profile so that the resulting compressed film has an undulating or wave-shaped surface profile.

According to one embodiment of the invention, the first and/or the second mould preferably has a minimum radius in the range of 5 cm to 50 cm. A suitable radius can be selected for example based on the thickness and mechanical properties of the graphene-based film used as a starting material and also based on the number of layers of films. A too small radius may lead to breaking of the film while a too large radius may not provide the desired effects in the terms of improved mechanical properties.

According to one embodiment of the invention, the first mould has a repeating triangle profile, and the second mould may either be flat or have a corresponding triangle profile with an offset of half a period so that the resulting compressed film has a triangular surface profile on both sides of the film. An opening angle between adjacent triangles is preferably in the range of 20° to 150° where a suitable angle can be selected based on the properties of the graphene based film. Analogously with the curved profile, a too small angle risks breaking the film with a too large angle between adjacent triangles, the advantageous mechanical effects may not be achieved.

According to one embodiment of the invention, the first mould is a cylindrical mould. The cylindrical mould may then be provided with a triangular or undulating profile to achieve the desired profile of the compressed film. Moreover, each of the first and second mould may be cylindrical profiled mould so that the stack of graphene-based films is pressed between two cylindrical rolls.

According to one embodiment of the invention, pressing the stack of graphene-based films between the first mould and the second mould comprises applying a pressure in the range of 1 MPa to 30 MPa.

According to one embodiment of the invention, infiltrating a polymer in the compressed film comprises using vacuum assisted infiltration. Moreover, the polymer has a molecular weight in the range of 10 000 g/mol and 500 000 g/mol.

According to one embodiment of the invention, curing comprises heating the infiltrated film to a temperature in the range of 80° C. to 200° C. and maintaining the temperature for a time period in the range of 1 h to 4 h, thereby hardening the polymer.

According to one embodiment of the invention, cutting the cured infiltrated film advantageously comprises using wire cutting or blade cutting. An advantage of using wire or blade cutting is that it provides a low surface roughness which is important for thermal interface pads used to conduct heat between two planar surfaces.

According to one embodiment of the invention the method further comprises coating edges of the thermal interface pad using a polymer such as a silicone, acrylic, polyurethane, polyethylene, polyimide, parylene or epoxy material. By coating the edges, fraying of the pad is avoided and the mechanical properties of the thermal interface pad is further improved.

According to one embodiment of the invention, the method further comprises coating edges of the graphene-enhanced thermal interface pad using a polymer or an epoxy material having a viscosity in the range of 1000 to 100000 mPa·s. The coating of the edges may improve the tensile strength of the interface pad in the direction perpendicular to the aligned direction by 20% up to 100% compared to thermal interface pad without edge-coating. The coating thereby prevents delamination of the thermal interface pad and also reduces the risk of fraying of the edges as well as reducing the amount of particles being released by the thermal interface pad.

According to one embodiment of the invention, the thermal interface pad has a thermal conductivity in a direction perpendicular to the plane of the film in the range of 25 W/mK to 200 W/mK. The thermal conductivity in the direction through the plane of the thermal interface pad is a key parameter in determining the efficiency of the thermal interface pad as a thermal interface material arranged to transport heat away from a component generating heat.

According to a second aspect embodiment of the invention, there is provided a polymer infiltrated graphene-enhanced thermal interface pad comprising: a plurality of strips of polymer infiltrated graphene-based film extending in the plane of the pad, wherein at least a portion of the strips are arranged in a curved or angled pattern along the extension of the strips in the plane of the pad. The curved pattern may be a single curve or a wave-shaped pattern, and the angled pattern may for example be a triangular pattern.

According to one embodiment of the invention, the polymer infiltrated graphene-enhanced thermal interface pad further comprises a coating in the form of a polymer or an epoxy material arranged at edges of the polymer infiltrated graphene-enhanced thermal interface pad.

Effects and features of this second aspect of the present invention are largely analogous to those described above in connection with the first aspect of the invention.

Further features of, and advantages with, the present invention will become apparent when studying the appended claims and the following description. The skilled person realizes that different features of the present invention may be combined to create embodiments other than those described in the following, without departing from the scope of the present invention.

### BRIEF DESCRIPTION OF THE DRAWINGS

These and other aspects of the present invention will now be described in more detail, with reference to the appended drawings showing an example embodiment of the invention, wherein:

FIGS. 1A-G schematically illustrate steps of a method according to an embodiment of the invention;

FIG. 2 is a flow chart outlining steps of a method according to an embodiment of the invention;

FIG. 3 schematically illustrate graphene-enhanced thermal interface pad according to an embodiment of the invention; and

FIGS. 4A-B schematically illustrate steps of a method and a graphene-enhanced thermal interface pad according to an embodiment of the invention.

FIG. 5 schematically illustrate steps of a method according to an embodiment of the invention

FIG. 6 schematically illustrate steps of a method according to an embodiment of the invention; and

FIGS. 7A-C schematically illustrate steps of a method and graphene-enhanced thermal interface pads according to embodiments of the invention.

### DETAILED DESCRIPTION OF EXAMPLE EMBODIMENTS

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person. Like reference characters refer to like elements throughout.

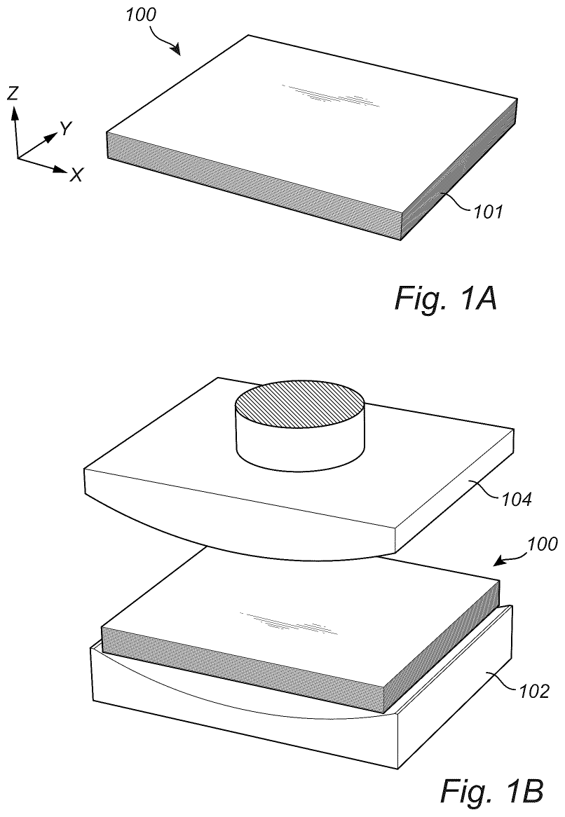

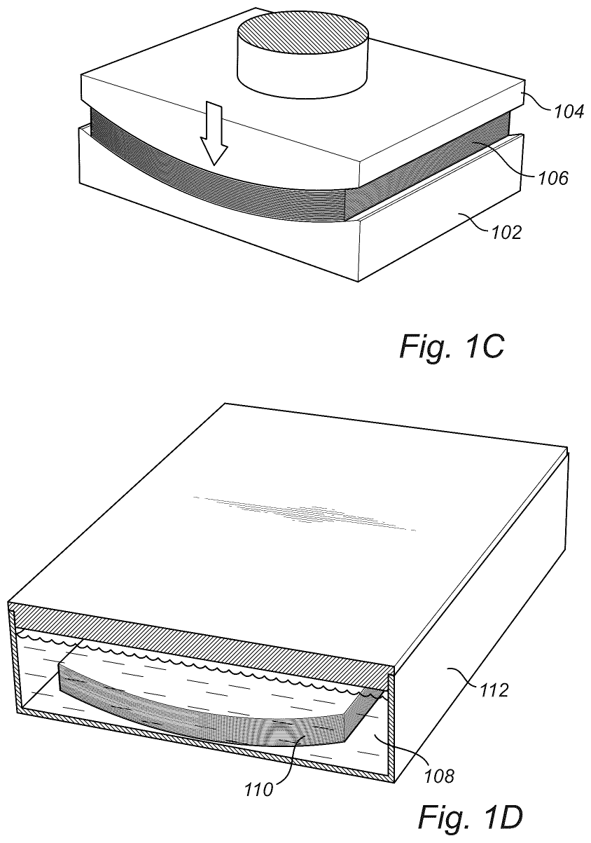

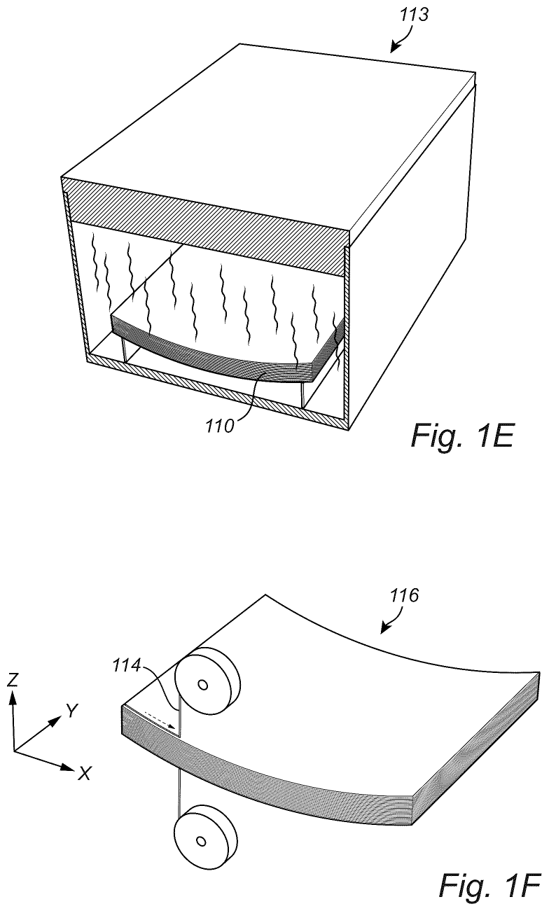

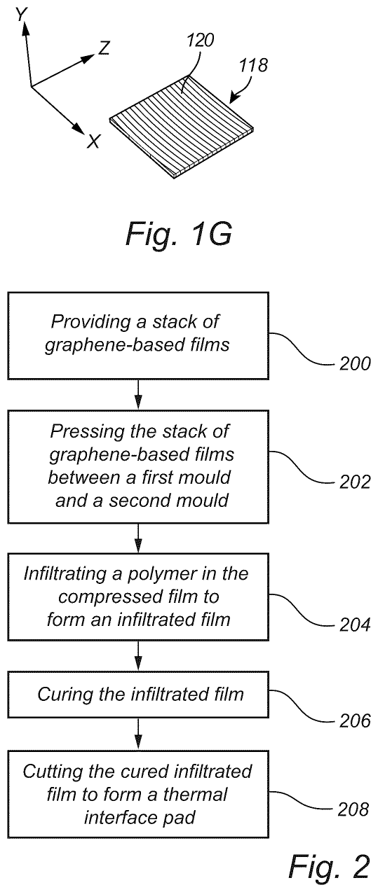

FIGS. 1A-G schematically illustrate a method of manufacturing a thermal interface pad 118 according to an embodiment of the invention and FIGS. 1A-G will be described with further reference to FIG. 2 showing a flow chart outlining steps of the method.

The first step of the method for manufacturing a thermal interface pad 118 the method comprises providing 200 a stack of graphene-based films 100 illustrated in FIG. 1A. The stack of graphene-based films 100 may comprise anywhere between 10 and 2000 layers of film, depending on the required size of the pad to be produced and on the thickness and size of an individual graphene-based film.

The manufacturing of graphene-based films is described elsewhere and only a general description will therefore be provided herein. For example, a graphene film suitable for use in the present context can be formed by providing graphene oxide sheets in an aqueous suspension; providing a substrate; dispensing the suspension on the substrate; heating the suspension on the substrate to form a graphene film by means of self-assembly; detaching the graphene film from the substrate; performing thermal annealing of the graphene film at a temperature in the range of 2800-3300° C. in an inert ambient; and pressing the graphene film at a pressure in the range of 50-300 MPa. By means of the above-described method, a large-scale method of producing a freestanding graphene-based film (GF) with an ultra-high in-plane thermal conductivity is provided. It should however be noted that graphene based films manufactured by other method may also be used in the describe method as long as the graphene-based film has a sufficiently high in-plane thermal conductivity.

The stack of graphene-based films 100 is arranged between a first mould 102 and a second mould 104. In FIG. 1B, the first mould 102 has a concave shape and the second mould 104 has a convex shape mirroring the shape of the first mould 102.

That the first and/or second mould has a profiled surface thereby means that there is a surface profile on a scale so that a majority of the films in the stack of films assume a shape corresponding to the profile of the mould.

The stack of graphene-based films 100 is subsequently pressed 202 between the first mould 102 and the second mould 104 to form a compressed film 106 as illustrated in FIG. 1C. Here it can that all of the films in the stack of films 100 assume the curved shape of the first and second mould 102, 104. Preferably, pressing 202 includes applying a pressure in the range of 1 MPa to 30 MPa. The resulting compressed film 106 illustrated in FIG. 1C thereby has a U-shaped profile following the first and second mold.

The next step, schematically illustrated in FIG. 1D, comprises infiltrating 204 a polymer 108 in the compressed film to form an infiltrated film 110. Polymer infiltration is for example performed using vacuum assisted infiltration where the compressed film 106 is placed in a sealed container 112 where a vacuum in the range of 10⁻² to 10⁻⁶ torr is formed and a polymer 108 is provided in the container to infiltrate the compressed film, thereby forming a polymer-infiltrated film 110. The polymer used for infiltration may be silicone, epoxy, acrylic or polyurethane or other polymers having similar properties and the wherein the polymer preferably has a molecular weight in the range of 10 000 g/mol to 500 000 g/mol. It would also be possible to use a wax or similar materials to infiltrate the compressed film.

Next, the polymer infiltrated film 110 is cured 206 in a heated chamber 113 to harden the polymer as illustrated in FIG. 1E. Depending on the type of polymer used, the temperatures and times for curing the polymer may vary. In an example implementation, curing 206 comprises heating the infiltrated film to a temperature in the range of 80° C. to 200° C. and maintaining the temperature for a time period in the range of 1 h to 4 h.

After curing, the cured infiltrated film 116 is cut 208 in a direction perpendicular to the plane of the graphene-based films using a wire saw 114 as seen in FIG. 1F to form a basis for the graphene-enhanced thermal interface pad 118 illustrated in FIG. 1G. The graphene-enhanced thermal interface pad 118 can either be taken directly as cut from the cured infiltrated film 116 or it can be subsequently cut to any suitable shape.

The plane of the cured infiltrated film 116 is defined as the xy-plane in FIG. 1F and the film 116 is thus cut in the z-direction so that the resulting polymer infiltrated graphene-enhanced thermal interface pad 118 comprises a plurality of strips 120 of polymer infiltrated graphene-based film extending in the plane of the pad 118, which will be the xz-plane using the coordinate system of FIG. 1F. Even though FIG. 1F illustrates using wire cutting, other cutting methods such as blade cutting are also possible. The thickness of the pad 118 can thereby be easily controlled in the range from approximately 50 μm up to several millimeters

Moreover, at least a portion of the strips 120 are arranged in a curving or angled pattern along the extension of the strips 120 in the plane of the pad 118, and further examples of possible orientations for the strips 120 of graphene-based film will be described in the following.

The curved mold results in a thermal interface pad 118 having curved strips 120 of the graphene based-film stacked in the plane of the pad 118, which in turn leads to improved mechanical properties of the thermal interface pad 118.

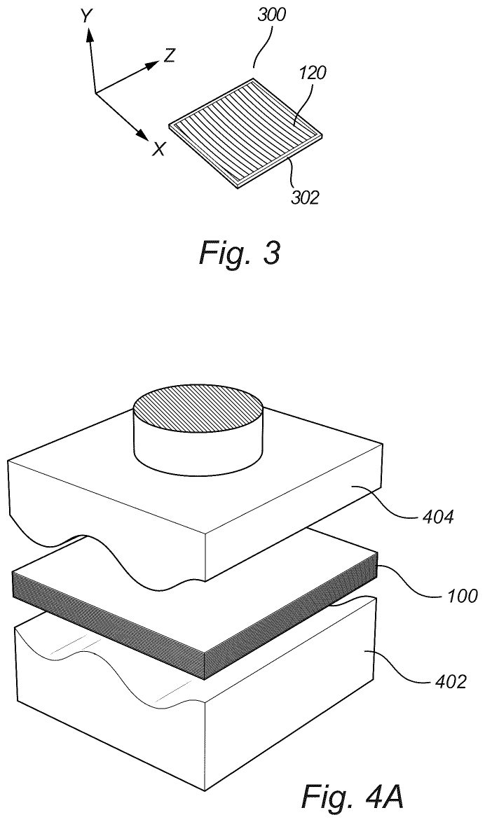

The method of manufacturing a thermal interface pad may further comprise coating edges of the thermal interface pad using a polymer or an epoxy material which preferably has a viscosity in the range of 1000 to 100000 mPa·s. A thermal interface pad 300 having coated edges 302 is schematically illustrated in FIG. 3. A coating may for example be applied by dipping the pad in a coating material. The coating improves the tensile strength of the pad in the plane of the pad in a direction perpendicular to the extension of the strips 120 of graphene based film, which is illustrated as the z-direction in FIG. 3. Depending on the type of coating, the tensile strength may be improved by 20% for a silicone coating and with an improvement of up to 100% for an epoxy coating. The coating also particle fall-off from the pad and reduces the risk of delamination.

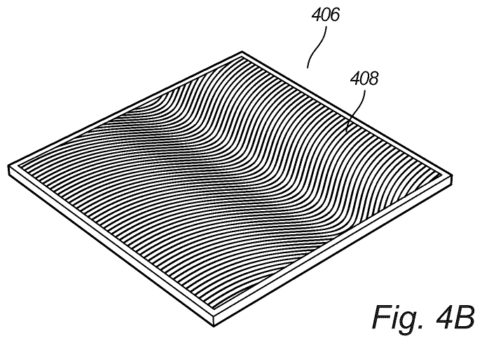

At least one of the first mould 402 and the second mould 404 may have an undulating or wave-shaped surface profile, and in FIG. 4A both of the first and second mould 402, 404 has a wave-shaped surface profile which results in a thermal interface pad 406 having strips 408 of graphene-based films in a wave-shaped alignment in the plane of the thermal interface pad 406 as illustrated in FIG. 4B. However, also irregular and/or free-form surface profiles of the first and/or second mould would be possible. The first and/or second profiled mould preferably has a minimum radius of the curved portion in the range of 5 cm to 50 cm where a suitable radius can be selected based on for example the thickness of the stack of graphene-based film, the proportions between the polymer and the graphene-based films and on the desired mechanical properties of the thermal interface pad.

Furthermore, even though the thermal interface pads are illustrated as rectangular pads, the pads can be arbitrarily shaped to suit any given application. A free-form of shape thermal interface pads is possible since the pad can be cut to a suitable shape by conventional cutting methods.

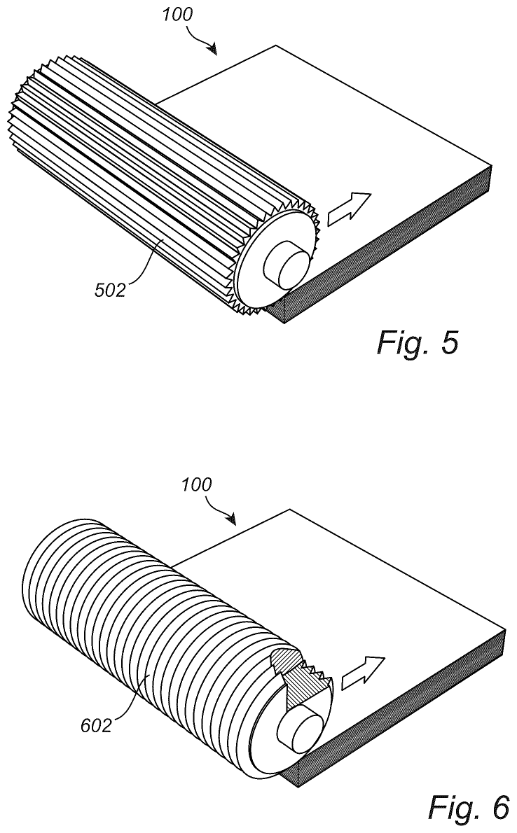

FIG. 5 schematically illustrates an example implementation where the first mould 502 is a roller having a profiled surface and the second mould (not shown) is a flat surface so that the stack of graphene-based films 101 is pressed between the roller and the flat surface. The first mould 502 has a triangular surface with ridges extending along the axial direction of the roller. The angle between adjacent ridges is here 90° and the distance between peaks is 150 μm, but angles may preferably range from 20° to 160° and it is also possible to provide an opposing roller so that the stack 100 of graphene-based films is pressed between two rollers.

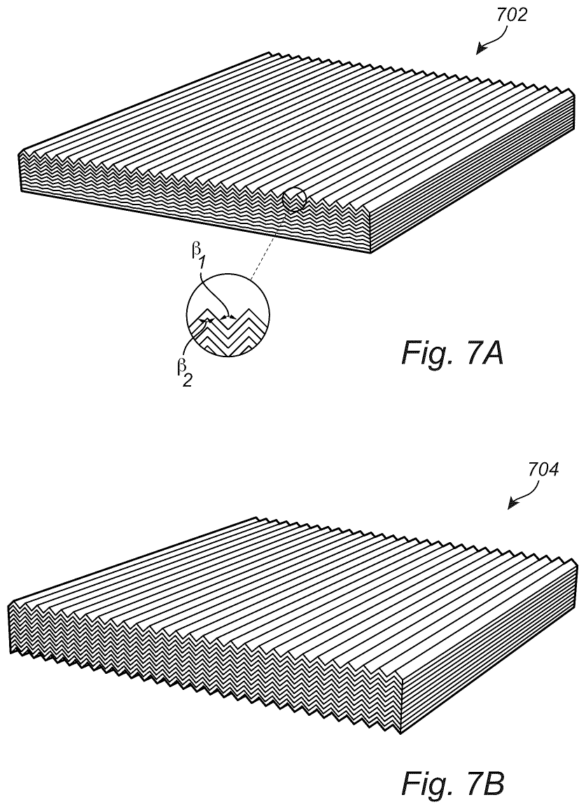

FIG. 6 show a similar example implantation as in FIG. 5 with the difference that the ridges of the first profiled mould 602 are arranged to extend around the circumference of the mould 602.

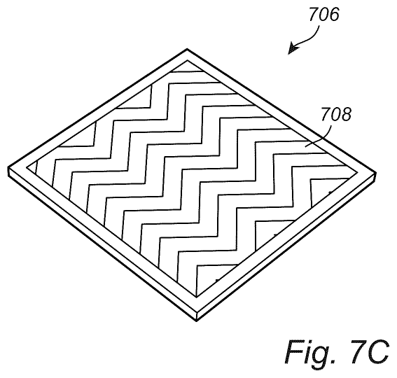

FIG. 7A schematically illustrates a compressed film 702 which has been pressed between a first profiled mould 502, 602 having a triangular surface profile and a second mould having a flat surface, and FIG. 7B illustrates a compressed film 704 having been pressed between a first and second mould 502, 602 each having triangular surface profiles. The compressed films 702, 704 may for example be formed by using the types of rollers 502, 602 illustrated in FIGS. 5-6. The angles β₁ and β₂ show the respective opening angle β₁ and peak angle β₂ of the triangle in the triangular profile.

FIG. 7C illustrates a thermal interface pad 706 comprising strips 708 of graphene film arranged in a triangular pattern, where the illustrated pad may be formed from a compressed and polymer infiltrated film as illustrated in FIG. 7B.

Even though the invention has been described with reference to specific exemplifying embodiments thereof, many different alterations, modifications and the like will become apparent for those skilled in the art. Also, it should be noted that parts of the method may be omitted, interchanged or arranged in various ways, the method yet being able to perform the functionality of the present invention.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage.

1. Method for manufacturing a thermal interface pad the method comprising:
providing a stack of graphene-based films;
pressing the stack of graphene-based films between a first mould, and a second mould to form a compressed film, wherein at least one of the first and second mould has a non-flat profiled surface;
infiltrating a polymer in the compressed film to form an infiltrated film;
curing the infiltrated film; and
cutting the cured infiltrated film in a direction perpendicular to the plane of the graphene-based films to form a graphene-enhanced thermal interface pad in which strips of graphene film follow the non-flat profile of the least one of the first and second mould in the plane of the pad.

2. The method according to claim 1, wherein the first mould has a concave profile.

3. The method according to claim 1, wherein the first mould has an undulating profile.

4. The method according to claim 2, wherein the first mould has a minimum radius in the range of 5 cm to 50 cm.

5. The method according to claim 1, wherein the first mould has a repeating triangle profile.

6. The method according to claim 5, wherein the opening angle between adjacent triangles is in the range of 20° to 150°.

7. The method according to claim 1, wherein the first mould is a cylindrical mould.

8. The method according to claim 1, wherein the second mould has a profile mirroring the profile of the first mould.

9. The method according to claim 1, wherein one of the first and second mould has a flat surface.

10. The method according to claim 1, wherein pressing the stack of graphene-based films between the first mould and the second mould comprises applying a pressure in the range of 1 MPa to 30 MPa.

11. The method according to claim 1, wherein infiltrating a polymer in the compressed film comprises using vacuum assisted infiltration.

12. The method according to claim 1, wherein curing comprises heating the infiltrated film to a temperature in the range of 80° C. to 200° C. and maintaining the temperature for a time period in the range of 1 h to 4 h.

13. The method according to claim 1, wherein the polymer has a molecular weight in the range of 10 000 g/mol to 500 000 g/mol.

14. The method according to claim 1, wherein cutting the cured infiltrated film comprises using wire cutting or blade cutting.

15. The method according to claim 1, further comprising coating edges of the thermal interface pad using a polymer or an epoxy material.

16. The method according to claim 1, further comprising coating edges of the thermal interface pad using a polymer or an epoxy material having a viscosity in the range of 1000 to 100000 mPa·s.

17. The method according to claim 1, wherein the thermal interface pad has a thermal conductivity in a direction perpendicular to the plane of the film in the range of 25 W/mK to 200 W/mK.

18. A polymer infiltrated graphene-enhanced thermal interface pad comprising:
a plurality of strips of polymer infiltrated graphene-based film extending in the plane of the pad, wherein at least a portion of the strips are arranged in a curved or angled pattern along the extension of the strips in the plane of the pad.

19. The polymer infiltrated graphene-enhanced thermal interface pad according to claim 18, wherein the pattern of the strips is a wave-shaped or triangular pattern.

20. (canceled)

21. The polymer infiltrated graphene-enhanced thermal interface pad according to claim 18, further comprising a coating polymer or an epoxy material arranged at edges of the polymer infiltrated graphene-enhanced thermal interface pad.
